(19) United States
(12) Patent Application Publication
(10) Pub. No.: US 2025/0126776 A1
(43) Pub. Date: Apr. 17, 2025

(54) SEMICONDUCTOR DEVICE, MANUFACTURING METHOD THEREFOR, AND ELECTRONIC EQUIPMENT

(71) Applicant: BEIJING SUPERSTRING ACADEMY OF MEMORY TECHNOLOGY, Beijing (CN)

(72) Inventors: Libin Jia, Beijing (CN); Yanlei Ping, Beijing (CN); Chao Tian, Beijing (CN)

(73) Assignee: BEIJING SUPERSTRING ACADEMY OF MEMORY TECHNOLOGY, Beijing (CN)

(21) Appl. No.: 18/692,472

(22) PCT Filed: Jun. 16, 2023
(86) PCT No.: PCT/CN2023/100804

§ 371 Date: Mar. 15, 2024

(30) Foreign Application Priority Data
Nov. 23, 2022 (CN) 202211476393.4

(51) Int. Cl. H10B 12/00; H01L 21/223; H01L 21/768; H10D 84/01

(52) U.S. Cl. CPC H10B 12/482; H01L 21/2236; H01L 21/76843; H01L 21/76897; H10B 12/053; H10D 84/016

(57) ABSTRACT

Disclosed are a semiconductor device, a manufacturing method therefor, and an electronic equipment, the semiconductor device includes: at least one vertical channel transistor disposed on a base substrate, and a bit line; the transistor includes a semiconductor pillar extending along a direction perpendicular to the base substrate, the semiconductor pillar includes a channel region, and a first region and a second region respectively disposed on two sides of the channel region, the second region is disposed between the base substrate and the first region, the bit line is in contact with the second region, and a plasma dopant concentration of a contact surface between the second region and the bit line is greater than or equal to 1e14 atoms/square centimeter.

### CROSS-REFERENCE TO RELATED APPLICATIONS

The present application is a U.S. National Phase Entry of International Application PCT/CN2023/100804 having an international filing date of Jun. 16, 2023, which claims priority to Chinese Patent Application No. 202211476393.4, filed to the CNIPA on Nov. 23, 2022 and entitled “Semiconductor Device, Manufacturing Method therefor, and Electronic Equipment”, contents of which should be construed as being incorporated herein by reference.

### TECHNICAL FIELD

Embodiments of the present disclosure relate to, but are not limited to, the field of semiconductor technologies, in particular to a semiconductor device, a method for manufacturing the semiconductor device, and an electronic equipment.

### BACKGROUND

Semiconductor storage may be divided into a volatile memory (Random Access Memory (RAM), including a Dynamic Random Access Memory (DRAM) and a Static Random Access Memory (SRAM), etc.) and a non-volatile memory (a Read Only Memory (ROM) and a non-ROM).

Taking a DRAM as an example, a conventional known DRAM has multiple repeated “storage units”, and each storage unit has a capacitor and a transistor. The capacitor may store 1-bit data. After charging and discharging, an amount of charge stored in the capacitor may correspond to binary data “1” and “0” respectively. The transistor is a switch that controls charging and discharging of the capacitor.

In order to reduce product costs as much as possible, it is desired to make as many storage units as possible on a limited base substrate. Since Moore's Law came out, the industry has proposed various semiconductor structure designs and process optimization to meet people's demand for current products.

### SUMMARY

The following is a summary of subject matter described in detail herein. The summary is not intended to limit the scope of protection of the claims.

An embodiment of the present disclosure provides a semiconductor device, including: at least one vertical channel transistor disposed on a base substrate, and a bit line; wherein each transistor includes a semiconductor pillar extending along a direction perpendicular to the base substrate, the semiconductor pillar includes a channel region, and a first region and a second region respectively disposed on two sides of the channel region, a bit line slot is disposed between a bottom of the second region of the semiconductor pillar and the base substrate, the bit line is filled in the bit line slot, the second region is disposed between the base substrate and the first region, the bit line is in contact with the second region, and a plasma dopant concentration of a contact surface between the second region and the bit line is greater than or equal to 1e14 atoms/square centimeter.

In some embodiments, the plasma dopant concentration of the contact surface between the second region and the bit line is 1e15 to 2e17 atoms/square centimeter.

In some embodiments, the semiconductor device includes a plurality of transistors distributed in an array along a first direction and a second region respectively, and a plurality of bit lines extending along the first direction, wherein second regions of transistors of a same column distributed along the first direction are connected with a same bit line, and the first direction and the second direction intersect.

In some embodiments, each transistor further includes: a gate electrode surrounding the channel region of the transistor, the semiconductor device further includes a plurality of word lines extending along the second direction, and gate electrodes of transistors of a same row distributed along the second direction are connected to form one word line.

An embodiment of the present disclosure provides a method for manufacturing a semiconductor device, wherein the semiconductor device includes at least one vertical channel transistor, the transistor includes a semiconductor pillar extending along a direction perpendicular to a base substrate, and the method includes: providing the base substrate, and forming a semiconductor pillar of the transistor and at least one trench exposing one side of the semiconductor pillar on the base substrate; wherein each trench includes a bottom wall and a side wall, and the semiconductor pillar includes a second region, a channel region, and a first region in sequence from the bottom wall of the trench to an opening direction of the trench; forming a first barrier layer covering a second side wall region of the trench and exposing the bottom wall and a first side wall region of the trench, wherein the first side wall region corresponds to the second region of the semiconductor pillar, and the second region is a region to be doped; and the second side wall region covers at least the channel region and the first region; the first side wall region is disposed on a side of the second side wall region close to the bottom wall, and the first side wall region includes at least a portion of the second region; performing plasma doping and annealing diffusion on at least the first side wall region exposed after being covered by the first barrier layer to complete ion doping of the second region; sheltering the second region after the ion doping, and etching the bottom wall of the trench to form a bit line slot, wherein the bit line slot exposes a bottom of the second region, and depositing a conductive thin film in the bit line slot to form a bit line, wherein a plasma dopant concentration of a contact surface between the second region and the bit line is greater than or equal to 1e14 atoms/square centimeter.

In some embodiments, forming the first barrier layer covering the second side wall region of the trench and exposing the bottom wall and the first side wall region of the trench includes: forming an isolation layer which fills the trench and whose height is a preset height, wherein the isolation layer covers the bottom wall and the first side wall region of the trench; forming the first barrier layer covering the second side wall region of the trench; and etching to remove the isolation layer to expose the bottom wall and the first side wall region of the trench.

In some embodiments, the isolation layer is a spin-on hard mask layer including carbon.

In some embodiments, after performing the plasma doping and the annealing diffusion on the first side wall region, and before etching the bottom wall of the trench to form the bit line slot, further including: removing the first barrier layer to form a second barrier layer covering the first side wall region and the second side wall region of the trench and exposing the bottom wall of the trench.

In some embodiments, when the plasma doping and the annealing diffusion are performed on the first side wall region, the plasma doping and the annealing diffusion are also performed on the bottom wall.

In some embodiments, forming the at least one semiconductor pillar extending along the direction perpendicular to the base substrate and the at least one trench on the base substrate includes: forming a plurality of semiconductor pillars extending along the direction perpendicular to the base substrate and distributed in an array along a first direction and a second direction respectively, and a plurality of trenches extending along the second direction on the base substrate, wherein each trench exposes two opposite sides of two adjacent rows of semiconductor pillars distributed along the second direction, and the first direction and the second direction intersect.

In some embodiments, the bit line slot extends along the first direction, and second regions of semiconductor pillars of a same column distributed along the first direction are connected with a same bit line.

An embodiment of the present disclosure provides an electronic equipment including the semiconductor device described in any of the above embodiments.

In some embodiments, the electronic equipment includes a smart phone, a computer, a tablet, artificial intelligence, a wearable device, or a smart mobile terminal.

Other features and advantages of the present disclosure will be set forth in the following specification, and moreover, partially become apparent from the specification, or are understood by implementing the present disclosure. The objectives and advantages of the present disclosure may be achieved through structures particularly pointed out in the specification and the drawings.

Other aspects may be understood upon reading and understanding the drawings and detailed description.

### BRIEF DESCRIPTION OF DRAWINGS

Accompanying drawings are used to provide further understanding of technical solutions of the present disclosure, constitute a part of the specification, and are used to explain the technical solutions together with the embodiments of the present disclosure but not to form limitations on the technical solutions of the present disclosure.

FIG. 1 is a schematic diagram of a semiconductor device according to a technical solution.

FIG. 2 is a schematic plan view of a semiconductor device according to an exemplary embodiment of the present disclosure.

FIG. 3 is a cross-sectional view of the semiconductor device shown in FIG. 2 along an aa′ direction.

FIG. 4A is a schematic diagram along an aa′ direction after a semiconductor pillar is formed according to an exemplary embodiment.

FIG. 4B is a schematic diagram along a cc′ direction after a semiconductor pillar is formed according to an exemplary embodiment.

FIG. 5A is a cross-sectional view along an aa′ direction after an isolation layer is formed according to an exemplary embodiment.

FIG. 5B is a cross-sectional view along a bb′ direction after an isolation layer is formed according to an exemplary embodiment.

FIG. 5C is a cross-sectional view along a cc′ direction after an isolation layer is formed according to an exemplary embodiment.

FIG. 5D is a cross-sectional view along a dd′ direction after an isolation layer is formed according to an exemplary embodiment.

FIG. 6A is a cross-sectional view along an aa′ direction after an isolation layer is etched back according to an exemplary embodiment.

FIG. 6B is a cross-sectional view along a bb′ direction after an isolation layer is etched back according to an exemplary embodiment.

FIG. 6C is a cross-sectional view along a cc′ direction after an isolation layer is etched back according to an exemplary embodiment.

FIG. 6D is a cross-sectional view along a dd′ direction after an isolation layer is etched back according to an exemplary embodiment.

FIG. 7A is a cross-sectional view along an aa′ direction after a first barrier layer is formed according to an exemplary embodiment.

FIG. 7B is a cross-sectional view along a bb′ direction after a first barrier layer is formed according to an exemplary embodiment.

FIG. 7C is a cross-sectional view along a cc′ direction after a first barrier layer is formed according to an exemplary embodiment.

FIG. 7D is a cross-sectional view along a dd′ direction after a first barrier layer is formed according to an exemplary embodiment.

FIG. 8A is a cross-sectional view along an aa′ direction after a first barrier layer is etched according to an exemplary embodiment.

FIG. 8B is a cross-sectional view along a bb′ direction after a first barrier layer is etched according to an exemplary embodiment.

FIG. 8C is a cross-sectional view along a cc′ direction after a first barrier layer is etched according to an exemplary embodiment.

FIG. 8D is a cross-sectional view along a dd′ direction after a first barrier layer is etched according to an exemplary embodiment.

FIG. 9A is a cross-sectional view along an aa′ direction after an isolation layer is etched away according to an exemplary embodiment.

FIG. 9B is a cross-sectional view along a bb′ direction after an isolation layer is etched away according to an exemplary embodiment.

FIG. 9C is a cross-sectional view along a cc′ direction after an isolation layer is etched away according to an exemplary embodiment.

FIG. 9D is a cross-sectional view along a dd′ direction after an isolation layer is etched away according to an exemplary embodiment.

FIG. 10 is a schematic diagram after a semiconductor pillar is doped according to an exemplary embodiment.

FIG. 11A is a cross-sectional view along an aa′ direction after annealing according to an exemplary embodiment.

FIG. 11B is a cross-sectional view along a bb′ direction after annealing according to an exemplary embodiment.

FIG. 11C is a cross-sectional view along a cc′ direction after annealing according to an exemplary embodiment.

FIG. 11D is a cross-sectional view along a dd′ direction after annealing according to an exemplary embodiment.

FIG. 12A is a cross-sectional view along an aa′ direction after a first barrier layer is etched away according to an exemplary embodiment.

FIG. 12B is a cross-sectional view along a bb′ direction after a first barrier layer is etched away according to an exemplary embodiment.

FIG. 12C is a cross-sectional view along a cc′ direction after a first barrier layer is etched away according to an exemplary embodiment.

FIG. 12D is a cross-sectional view along a dd′ direction after a first barrier layer is etched away according to an exemplary embodiment.

FIG. 13A is a cross-sectional view along an aa′ direction after a second barrier layer is formed according to an exemplary embodiment.

FIG. 13B is a cross-sectional view along a bb′ direction after a second barrier layer is formed according to an exemplary embodiment.

FIG. 13C is a cross-sectional view along a cc′ direction after a second barrier layer is formed according to an exemplary embodiment.

FIG. 13D is a cross-sectional view along a dd′ direction after a second barrier layer is formed according to an exemplary embodiment.

FIG. 14A is a cross-sectional view along an aa′ direction after a bit line slot is formed according to an exemplary embodiment.

FIG. 14B is a cross-sectional view along a bb′ direction after a bit line slot is formed according to an exemplary embodiment.

FIG. 14C is a cross-sectional view along a cc′ direction after a bit line slot is formed according to an exemplary embodiment.

FIG. 14D is a cross-sectional view along a dd′ direction after a bit line slot is formed according to an exemplary embodiment.

FIG. 15A is a cross-sectional view along an aa′ direction after a bit line is formed according to an exemplary embodiment.

FIG. 15B is a cross-sectional view along a bb′ direction after a bit line is formed according to an exemplary embodiment.

FIG. 15C is a cross-sectional view along a cc′ direction after a bit line is formed according to an exemplary embodiment.

FIG. 15D is a cross-sectional view along a dd′ direction after a bit line is formed according to an exemplary embodiment.

FIG. 16 is a flowchart of a method for manufacturing a semiconductor device according to an exemplary embodiment.

### DETAILED DESCRIPTION

The embodiments of the present disclosure will be described in detail below in conjunction with the accompanying drawings. The embodiments in the present application and features in the embodiments may be combined with each other randomly if there is no conflict.

Unless otherwise defined, technical terms or scientific terms used in the present disclosure shall have general meanings as understood by those of ordinary skills in the art to which the present disclosure pertains.

The embodiments of the present disclosure are not necessarily limited to dimensions shown in the drawings, and shapes and sizes of various components in the drawings do not reflect actual scales. Further, the drawings schematically illustrate ideal examples, but embodiments of the present disclosure are not limited to shapes or values shown in the drawings.

Ordinal numerals such as “first”, “second” and “third” in the present disclosure are provided to avoid confusion between constituent elements, but do not indicate any order, quantity or importance.

In the present disclosure, for convenience, words and expressions indicating orientation or positional relationship such as “middle”, “upper”, “lower”, “front”, “rear”, “vertical”, “horizontal”, “top”, “bottom”, “inner” and “outer” are employed to explain the positional relationship of the constituent elements with reference to the accompanying drawings, they are employed for ease of description and simplification of the description only, but do not indicate or imply that the referred device or element must have a particular orientation, be constructed and operate in a particular orientation, and therefore cannot be construed as limitations on the present disclosure. The positional relationship of the constituent elements is appropriately changed according to a direction in which each constituent element is described. Therefore, it is not limited to the words and expressions described in the present disclosure, and may be appropriately replaced according to the situation.

In the present disclosure, terms “mounted”, “connected” and “connection” are to be understood in a broad sense, unless otherwise expressly specified and defined. For example, a connection may be a physical connection or a signal connection; it may be a contact connection or an integrated connection; it may be a direct connection, indirect connection through middleware, or internal communication between two elements. For those of ordinary skills in the art, specific meanings of the above terms in the present disclosure may be understood according to actual situations.

In the present disclosure, a transistor refers to an element including at least three terminals, i.e., a gate, a drain, and a source. The transistor has a channel region between the drain and the source, and a current can flow through the drain, the channel region, and the source. In the present disclosure, the channel region refers to the region through which the current mainly flows.

In the present disclosure, an “electrical connection” includes a case where constituent elements are connected together through an element having a certain electrical effect. There are no special restrictions on “element having a certain electrical effect” as long as they can send and receive electrical signals between connected constituent elements. Examples of “element having a certain electrical effect” include not only electrodes and wirings, but also switching elements such as transistors, resistors, inductors, capacitors, and other elements having various functions, etc.

In the present disclosure, “parallel” refers to a state in which an angle formed by two straight lines is above −10° and below 10°. Therefore, it also includes a state in which the angle is above −5° and below 5°. In addition, “perpendicular” refers to a state in which an angle formed by two straight lines is above 80° and below 100°, and thus also includes a state in which the angle is above 85° and below 95°.

A transistor involved in an embodiment of the present application is a vertical transistor, and a length direction of a channel of the transistor is perpendicular to a base substrate. In the transistor in the embodiment of the present application, a silicon pillar on a silicon base substrate is used as a semiconductor pillar (channel). In some embodiments, bit lines in a storage unit array are buried and placed under the silicon pillar. A material of the bit lines may include a metal such as Titanium (Ti), Cobalt (Co), Nickel (Ni), Wolfram (W), an alloy, a metal nitride, or a metal silicide, etc. Contact between a bit line and a bottom of the silicon pillar is a Schottky basis, and a contact resistance needs to be further reduced.

To reduce the contact resistance, in some embodiments, a bottom region of the silicon pillar in contact with the bit line is doped with a high concentration to reduce a contact resistance between the bit line and the bottom of the silicon pillar to even achieve ohmic contact.

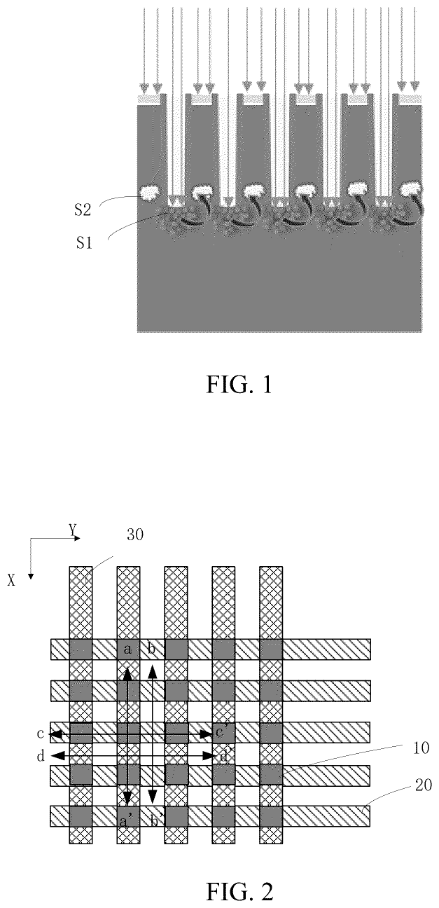

As shown in FIG. 1, plasma doping is carried out in a bottom region of a trench on a silicon base substrate, and a side wall of the trench is protected by an isolation layer, so plasma doping is only formed in a certain region at a bottom of the trench, such as a doped region S1 shown in FIG. 1. In this case, a plasma doped region does not completely cover a region directly under a silicon pillar. Then, doped ions in the doped region S1 are diffused to a bottom region S2 of the silicon pillar through an annealing process. In order to ensure insulation between two silicon pillars, the doped region S1 will be excavated away in a subsequent process. In a practical application scenario, since the plasma doped region S1 at the bottom of the trench is far away from the bottom region S2 of the silicon pillar, effective doping depends on annealing diffusion time (which requires a relatively long annealing diffusion time), and a doping utilization rate is low, it is relatively difficult to achieve high-concentration doping of the bottom region of the silicon pillar, especially it is relatively difficult to achieve that a doping concentration required for ohmic contact, which is not less than 1e14 atoms/square centimeter (atoms/cm)²).

In the above solution, not only a process is complicated, but also an effect after doping is difficult to be ensured.

In an embodiment of the present disclosure, a region of a side wall of a semiconductor pillar that needs to be doped is directly doped to achieve high-concentration doping of a bottom region of the semiconductor pillar, thereby reducing a contact resistance between a bit line and the semiconductor pillar, reducing dependence of doping on annealing diffusion, so that high-concentration doping in a relatively short time can be achieved, and a doping efficiency can be improved.

In the present disclosure, a base substrate 1 has two main surfaces and a side surface between the main surfaces, and the two main surfaces are respectively an upper surface and a lower surface which are oppositely disposed. The upper surface is a surface on which a transistor is disposed, being parallel to the base substrate 1 means being parallel to the lower surface of the base substrate 1, and being perpendicular to the base substrate 1 means being perpendicular to the lower surface of the base substrate 1. Before forming a semiconductor pillar 10, the base substrate 1 refers to an entire base substrate (including a semiconductor region for manufacturing the semiconductor pillar 10), and after the semi-conducting layer 10 is formed, the base substrate 1 refers to a region below the transistor in the entire base substrate.

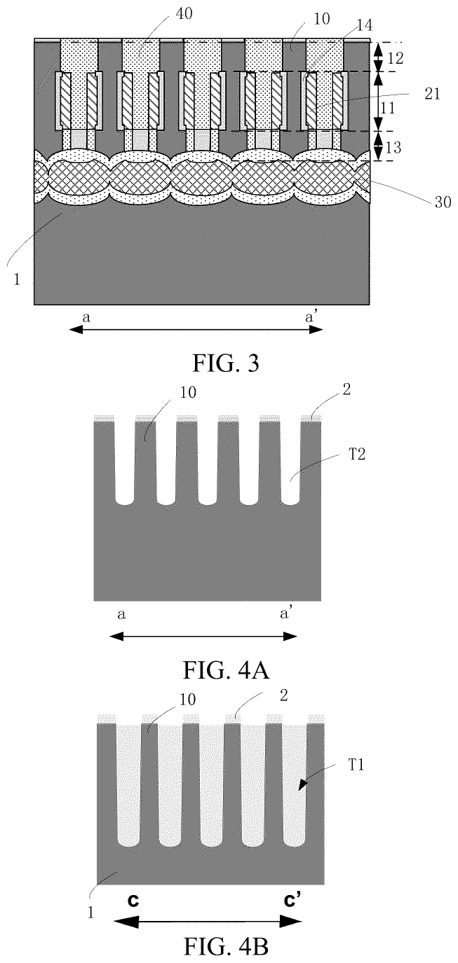

FIG. 2 is a schematic plan view of a semiconductor device according to an exemplary embodiment and FIG. 3 is a cross-sectional view of the semiconductor device along an aa′ direction. As shown in FIGS. 2 and 3, an embodiment of the present disclosure provides a semiconductor device including at least one vertical channel transistor disposed on a base substrate, and a bit line 30. Each transistor includes a semiconductor pillar 10 extending along a direction perpendicular to the base substrate, and the semiconductor pillar 10 includes a channel region 11 as well as a first region 12 and a second region 13 respectively disposed on two sides of the channel region 11. The second region 13 is disposed between the base substrate 1 and the channel region 11, the bit line 30 is in contact with the second region 13, and a concentration of a plasma dopant of a contact surface between the second region 13 and the bit line 30 is greater than or equal to 1e14 atoms/square centimeter. That is, a surface of the semiconductor pillar 10 close to the bit line 30 includes a plasma dopant, and a concentration of the plasma dopant is greater than or equal to 1e14 atoms/square centimeter (atoms/cm²).

According to a solution provided in the embodiment, high-concentration doping of 1e14 atoms/square centimeter or more is formed on a surface of a bottom (i.e., a side close to the bit line 30) of the semiconductor pillar to achieve ohmic contact between a bit line and the semiconductor pillar, thereby reducing a contact resistance between the bit line and a second region.

In some embodiments, one of the first region 12 and the second region 13 is a source region (a region in contact with a source electrode) and the other of the first region 12 and the second region 13 is a drain region (a region in contact with a drain electrode). For example, the first region 12 may be a source region and the second region 13 may be a drain region; or, the first region 12 may be a drain region and the second region 13 may be a source region.

In some embodiments, the concentration of the plasma dopant of the contact surface between the second region 13 and the bit line 30 may be 1e15 to 2e17 atoms/cm².

In some embodiments, the transistor may further include a gate insulation layer 14 surrounding the channel region 11.

In some embodiments, the semiconductor device is a storage array, the storage array may include a plurality of vertical channel transistors arranged in an array along a first direction X and a second direction Y, respectively, a plurality of bit lines 30 extending along the first direction X, and a plurality of word lines 20 extending along the second direction Y. A portion of each word line 20 surrounding a channel region 11 of a semiconductor pillar 10 may be used as a gate electrode, and the word line 20 is insulated from the channel region 11 through the gate insulation layer 14. The storage array may further include an isolation structure 40. The isolation structure 40 insulates different transistors.

In some embodiments, the isolation structure 40 may include a nitride, such as Silicon Nitride (SiN).

In some embodiments, the first direction X and the second direction Y may be perpendicular to each other. However, the embodiments of the present disclosure are not limited thereto, and the first direction X and the second direction Y may intersect.

In some embodiments, second regions 13 of transistors of a same column distributed along the first direction X are connected with a same bit line 30.

In some embodiments, a transistor may further include a gate electrode 21 surrounding the channel region 11 of the transistor, gate electrodes 21 of transistors of a same row distributed along the second direction Y are connected with a same word line 20 and used as a portion of the connected word line 20. That is, the gate electrodes 21 of the transistors in the same row distributed along the second direction Y are connected to form the word line 20.

Technical solutions of the embodiments will be further explained through a manufacturing process of the semiconductor device of the embodiment. A “patterning process” mentioned in the embodiments includes film layer deposition, photoresist coating, mask exposure, development, etching, photoresist stripping, and other treatments, and is a mature manufacturing process in related technologies. A “photolithography process” in the embodiments includes film layer coating, mask exposure, and development, and is a mature manufacturing process in the related technologies. Known processes such as sputtering, evaporation, chemical vapor deposition may be used for the deposition, known coating processes may be used for the coating, and known approaches may be used for etching, which are not specifically limited here. In description of the embodiments, it should be understood that a “thin film” refers to a layer of thin film made of a certain material on a base substrate using a deposition or coating process. If the “thin film” does not need a patterning process or photolithography process during the whole manufacturing process, the “thin film” may also be called a “layer”. If the “thin film” needs a patterning process or photolithography process during the whole manufacturing process, it is called a “thin film” before the patterning process and a “layer” after the patterning process. The “layer” after the patterning process or photolithography process contains at least one “pattern”.

In some embodiments, the manufacturing process of the semiconductor device may include following:

1) Forming a plurality of first trenches T1 extending along a first direction X on a base substrate 1, depositing an insulation thin film on the base substrate 1 to form an insulation layer 2, wherein the insulation layer 2 fills the first trenches T1, and then forming a plurality of second trenches T2 extending along a second direction Y. At this time, a plurality of semiconductor pillar bodies are formed on the base substrate 1 through the first trenches T1 and the second trenches T2, the plurality of semiconductor pillar bodies are used as semiconductor pillars 10 of a plurality of transistors, respectively, as shown in FIGS. 4A and 4B. FIG. 4A is a schematic diagram in an aa′ direction and FIG. 4B is a schematic diagram in a cc′ direction.

In some embodiments, the base substrate 1 may be a semiconductor base substrate; for example, it may include at least one simple-substance semiconductor material (e.g., a Silicon (Si) base substrate and a Germanium (Ge) base substrate), at least one III-V compound semiconductor material (e.g., a Gallium Nitride (GaN) base substrate, a Gallium Arsenide (GaAs) base substrate, and an Indium Phosphide (InP) base substrate), at least one II-VI compound semiconductor material, at least one organic semiconductor material, or another semiconductor material known in the art.

In some embodiments, the insulation thin film may be any one or more of Silicon Nitride (SiNₓ), Silicon Oxide (SiOₓ), Silicon Oxynitride (SiON), and Silicon Carbide (SiC).

In some embodiments, the semiconductor pillars 10 may be ion-implanted according to requirements for a first region 12, a second region 13, and a channel region 11 before forming the plurality of second trenches T2.

In some embodiments, a depth of a first trench T1 is greater than a depth of a second trench T2 along a direction perpendicular to the base substrate 1.

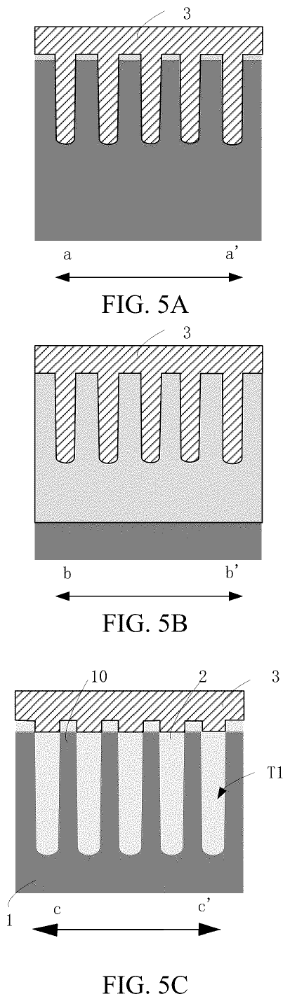

2) Filling the second trenches T2 and performing planarization to form an isolation layer 3, as shown in FIGS. 5A, 5B, 5C, and 5D, FIG. 5A is a cross-sectional view along the aa′ direction, FIG. 5B is a cross-sectional view along a bb′ direction, FIG. 5C is a cross-sectional view in the cc′ direction, and FIG. 5D is a cross-sectional view along a dd′ direction.

In some embodiments, the second trenches T2 may be filled by spin coating.

In some embodiments, the isolation layer 3 may be a Spin-On Hard mask (SOH) layer containing carbon.

In some embodiments, the planarization may be performed on the isolation layer 3 through Chemical Mechanical Polishing (CMP).

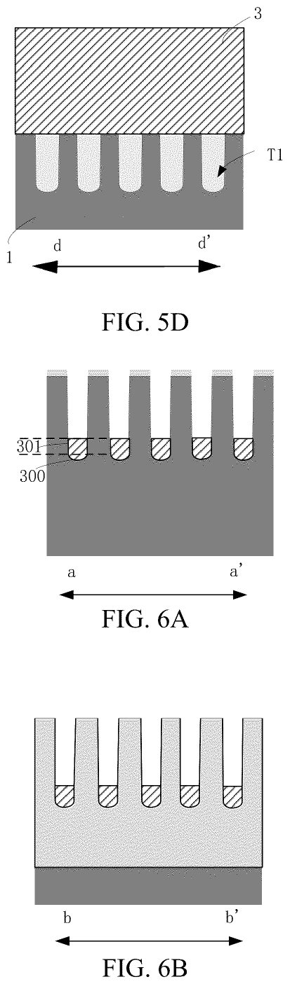

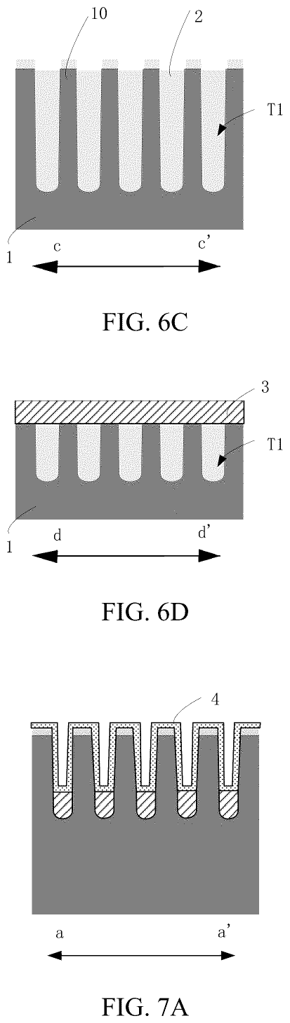

3) Etching back the isolation layer 3 using an etching process, and retaining the isolation layer 3 with a preset height at the bottom of each second trench T2, and the isolation layer 3 may cover a bottom wall 300 and a first side wall region 301, as shown in FIGS. 6A, 6B, 6C, and 6D. FIG. 6A is a cross-sectional view along the aa′ direction, FIG. 6B is a cross-sectional view along the bb′ direction, FIG. 6C is a cross-sectional view along the cc′ direction, and FIG. 6D is a cross-sectional view along the dd′ direction.

The preset height may be determined according to a contact position of a bit line 30 with a semiconductor pillar 10, and a first distance between an upper surface of the retained isolation layer 3 and a lower surface of the base substrate 1 is larger than a second distance between the contact position of the bit line 30 with the semiconductor pillar 10 and the lower surface of the base substrate 1, so that subsequently plasma doping can be directly performed on the contact position of the bit line 30 with the semiconductor pillar 10, and a relatively high doping concentration may be achieved. The lower surface of the base substrate 1 is a surface away from the insulation layer 2, and the upper surface of the insulation layer 3 is a surface close to the insulation layer 2.

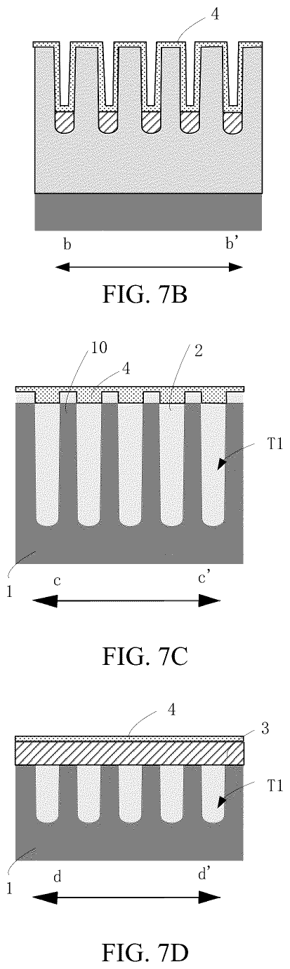

4) Depositing a first barrier layer thin film on the base substrate 1 where the aforementioned structures are formed to form a first barrier layer 4, as shown in FIGS. 7A, 7B, 7C, and 7D. FIG. 7A is a cross-sectional view along the aa′ direction, FIG. 7B is a cross-sectional view along the bb′ direction, FIG. 7C is a cross-sectional view along the cc′ direction, and FIG. 7D is a cross-sectional view along the dd′ direction.

In some embodiments, the first barrier layer thin film may be deposited using an Atomic Layer Deposition (ALD) process.

In some embodiments, the first barrier layer thin film may include, but is not limited to, a material having an etching selectivity ratio with the semiconductor pillar, such as Silicon Nitride (SiN).

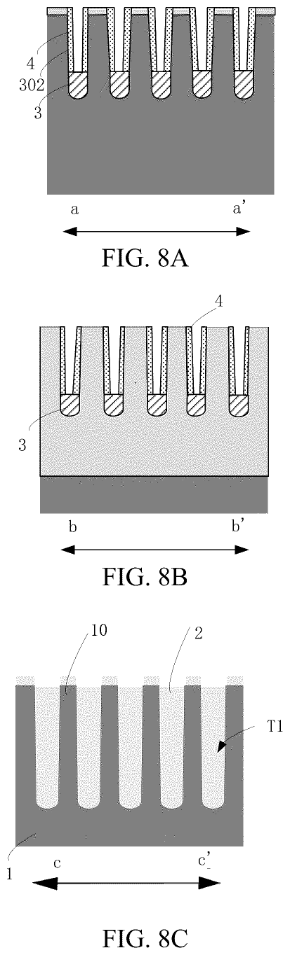

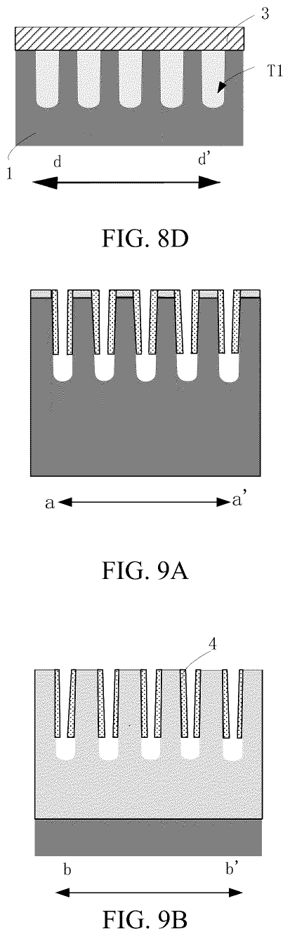

5) Etching the first barrier layer 4 to expose the isolation layer 3 located in a second trench T2, as shown in FIGS. 8A, 8B, 8C, and 8D. FIG. 8A is a cross-sectional view along the aa′ direction, FIG. 8B is a cross-sectional view along the bb′ direction, FIG. 8C is a cross-sectional view along the cc′ direction, and FIG. 8D is a cross-sectional view along the dd′ direction. At this time, the first barrier layer 4 covers a second side wall region 302 of the second trench T2 and serves as a selective shielding side wall for subsequent plasma doping to protect a side wall of a semiconductor pillar 10.

In some embodiments, the first barrier layer 4 may be etched using a dry etching process.

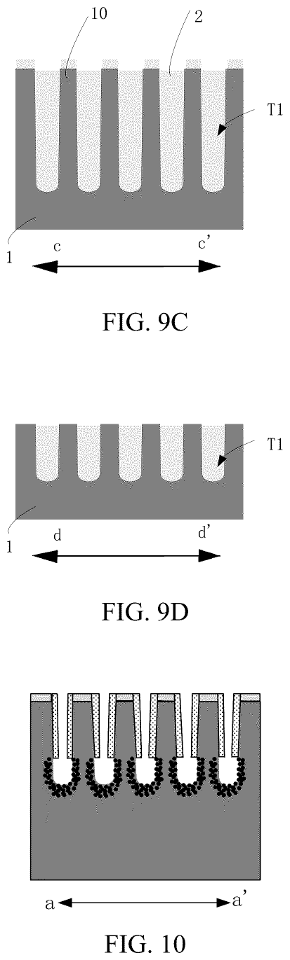

6) Etching away the isolation layer 3 to expose the bottom wall 300 and the first side wall region 301 of the second trench T2, as shown in FIGS. 9A, 9B, 9C, and 9D. FIG. 9A is a cross-sectional view along the aa′ direction, FIG. 9B is a cross-sectional view along the bb′ direction, FIG. 9C is a cross-sectional view along the cc′ direction, and FIG. 9D is a cross-sectional view along the dd′ direction.

In some embodiments, oxygen plasma (O² plasma) may be used for etching the isolation layer 3. O² plasma burns the insulation layer 3 without damaging the base substrate 1 (e.g., silicon), the insulation layer 2 (e.g., SiO₂), and the first barrier layer 4 (e.g., SiN).

7) Doping the bottom wall 300 and the first side wall region 301 of the second trench T2, as shown in FIG. 10, which only shows a schematic view in the aa′ direction, and black particles in FIG. 10 are dopants. According to a solution provided in the embodiment, both the bottom wall 300 and the side wall region 301 are doped and it is not necessary to only directionally dope the bottom wall 300, thus directivity of doping is relatively low and energy is lower than that of directional doping.

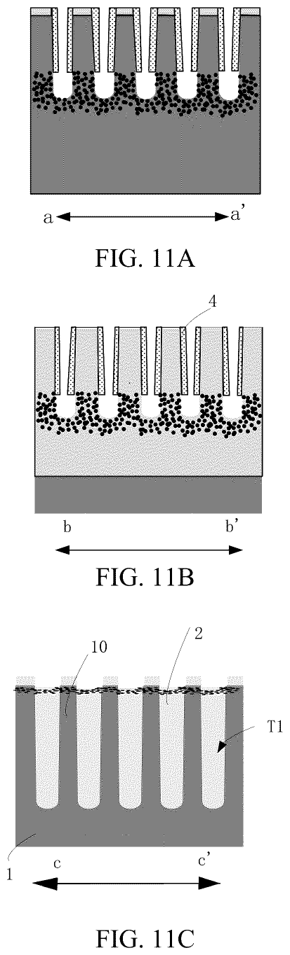

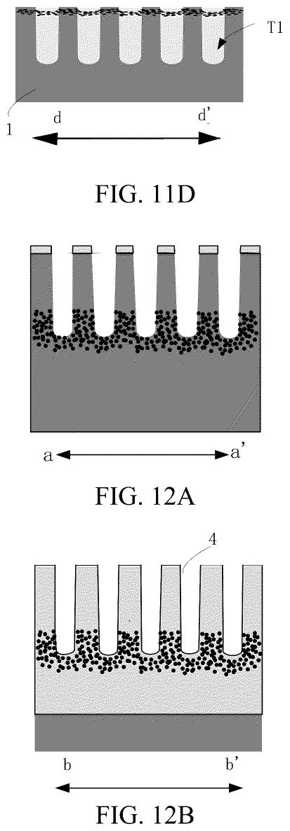

After that, annealing is performed so that an impurity doped in the bottom wall 300 and the first side wall region 301 of the second trench T2 diffuse to a peripheral region, as shown in FIGS. 11A, 11B, 11C, and 11D. FIG. 11A is a cross-sectional view along the aa′ direction, FIG. 11B is a cross-sectional view along the bb′ direction, FIG. 11C is a cross-sectional view along the cc′ direction, and FIG. 11D is a cross-sectional view along the dd′ direction. According to a solution provided in the embodiment, since the bottom wall 300 and the first side wall region 301 are doped, a larger doped surface is achieved. Compared with a solution of only doping the bottom wall 300, annealing time for doping on the bottom of the semiconductor pillar to reach a required concentration is greatly reduced.

In some embodiments, the bottom wall 300 and the first side wall region 301 of the second trench T2 may be doped with low energy and large dose, for example, a doping dose may be 1e19 to 1e22 atoms/cm² and doping energy may be less than or equal to 10 kiloelectron volts (keV).

In some embodiments, non-directional doping may be achieved using plasma doping. However, the embodiments of the present disclosure are not limited thereto, for example, doping may be performed in by ion implantation, and the doping by ion implantation is similar to non-directional doping when the doping energy may be less than or equal to 10 kiloelectron volts (keV).

In some embodiments, an appropriate doping impurity may be selected according to a device type. For example, for an N Metal Oxide Semiconductor (NMOS), Hydrogen Arsenide (AsH₃) or Phosphine (PH₃) plasma may be selected for doping a silicon pillar, and for a P Metal Oxide Semiconductor (PMOS), Boron trifluoride (BF₃) or diborane (B₂H₆) plasma may be selected for doping a silicon pillar.

In some embodiments, a plasma doping concentration of the contact surface between the bit line 30 and the semiconductor pillar 10 may be 1e15 to 2e17 atoms/cm², so that the contact resistance between the bit line 30 and the bottom of the semiconductor pillar 10 is lower.

In some embodiments, the annealing may be performed using a Rapid Thermal Processing (RTP) process.

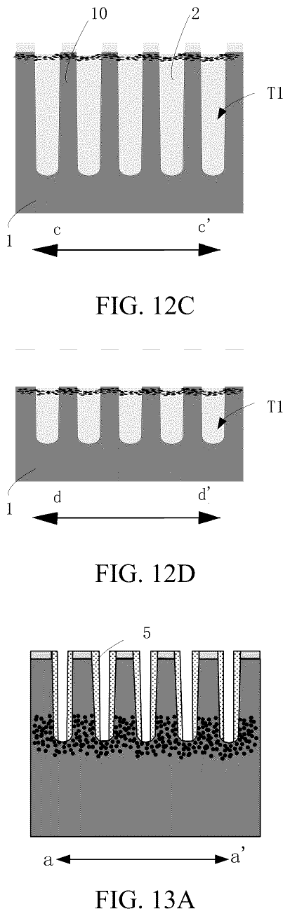

8) Etching to remove the first barrier layer 4, as shown in FIGS. 12A, 12B, 12C, and 12D. FIG. 12A is a cross-sectional view along the aa′ direction, FIG. 12B is a cross-sectional view along the bb′ direction, FIG. 12C is a cross-sectional view along the cc′ direction, and FIG. 12D is a cross-sectional view along the dd′ direction.

In some embodiments, the first barrier layer 4 may be removed by etching using a wet etch process (i.e., a wet etching process).

In some embodiments, when etching using a wet etching process, phosphoric acid with a preset ratio and temperature may be selected, so that the first barrier layer 4 (which may be manufactured using SiN) is etched without damaging the base substrate 1 (which may be manufactured using silicon), but the embodiments of the present disclosure are not limited thereto, and another etching solution may be used.

So far, high-concentration doping of a bottom surface of the semiconductor pillar 10 is completed.

9) Depositing a second barrier layer thin film on the base substrate 1 where the aforementioned structures are formed to form a second barrier layer 5. A purpose of the second barrier layer 5 is to shelter a doped region on a side wall of the semiconductor pillar 10 and etch an opening only on a bottom of a trench.

The second barrier layer 5 may be formed directly on the first barrier layer 4, or the first barrier layer 4 may be removed and then the second barrier layer 5 may be formed in the whole trench.

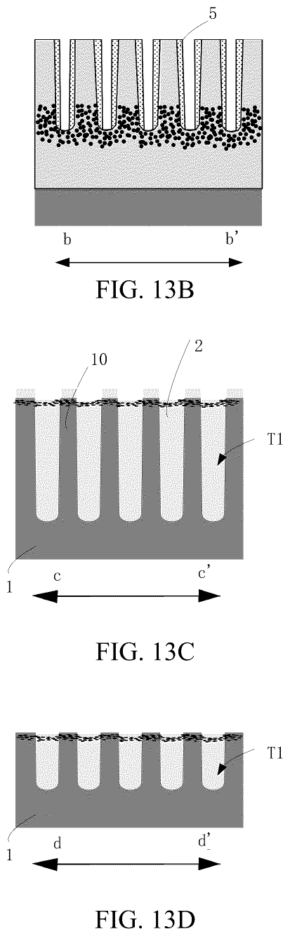

The second barrier layer 5 distributed on a side wall and the bottom of the trench is etched to expose only a bottom wall 300 of a second trench T2 without exposing a side wall of the second trench T2, especially without exposing a doped region, as shown in FIGS. 13A, 13B, 13C, and 13D. FIG. 13A is a cross-sectional view along the aa′ direction, FIG. 13B is a cross-sectional view along the bb′ direction, FIG. 13C is a cross-sectional view along the cc′ direction, and FIG. 13D is a cross-sectional view along the dd′ direction. At this time, the second barrier layer 5 covers the side wall of the second trench T2 (including the first side wall region 301 and the second side wall region 302, that is, the first side wall region 301 and the second side wall region 302 constitute the side wall of the second trench T2), and the second barrier layer 5 shelters the side wall of the second trench T2 so as to protect the semiconductor pillar 10 in a subsequent process.

In some embodiments, the second barrier layer thin film may be deposited using an ALD process, the trench is not completely filled after the deposition, and longitudinal etching may be performed to form an opening at the bottom of the trench without further trenching. The opening passes through a corresponding region of one row or one column of transistors along the second trench T2.

In some embodiments, the second barrier layer thin film includes, but is not limited to, SiN.

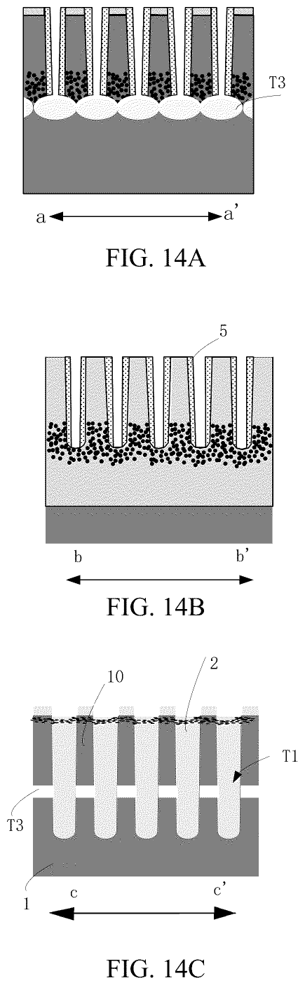

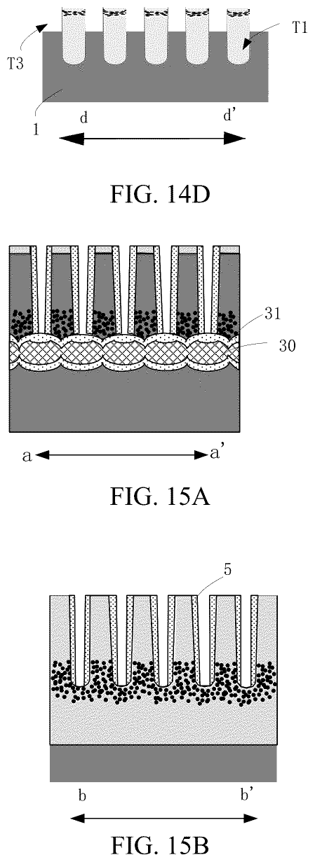

10) On a basis of the step 9, etching the base substrate 1 at the opening at the bottom of the second trench T2 on the second barrier layer 5 to form a plurality of bit line slots T3. The plurality of bit line slots T3 extends along a first direction X and are distributed at intervals in a second direction Y, and are adjacent to one row or one column of transistors in the first direction X. The bit line slots T3 extend along longitudinal and transverse directions, exposing a bottom of each second region 13 of a same column of semiconductor pillars 10 distributed along the first direction X, and the bottom of each second region 13 of the same row of semiconductor pillars 10 is communicated through the bit line slots T3, as shown in FIG. 14A, FIG. 14B, FIG. 14C, and FIG. 14D. FIG. 14A is a cross-sectional view along the aa′ direction, FIG. 14B is a cross-sectional view along the bb′ direction, FIG. 14C is a cross-sectional view along the cc′ direction, and FIG. 14D is a cross-sectional view along the dd′ direction.

In some embodiments, the base substrate 1 may be etched using a dry etching process to obtain the bit line slots T3.

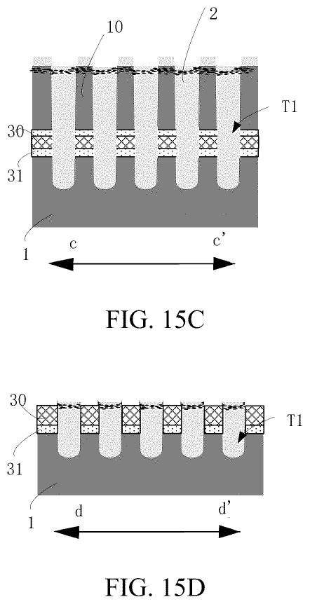

11) Sequentially depositing a connection layer thin film and a conductive thin film on the base substrate 1 where the aforementioned structures are formed, and etching to remove the connection layer thin film and the conductive thin film outside the bit line slots T3 to form a connection layer 31 and a bit line 30, as shown in FIGS. 15A, 15B, 15C, and 15D. FIG. 15A is a cross-sectional view along the aa′ direction, FIG. 15B is a cross-sectional view along the bb′ direction, FIG. 15C is a cross-sectional view along the cc′ direction, and FIG. 15D is a cross-sectional view along the dd′ direction.

In some embodiments, the connection layer 31 is annealed to form Silicide (a metal silicide) with silicon in the second region 13. The metal silicide connection layer 31, compared with a metal, can further reduce the contact resistance between the bit line 30 and the semiconductor pillar 10.

In some embodiments, the connection layer 31 is made of, for example, a silicide of Titanium (Ti), Cobalt (Co), Nickel (Ni), or Nickel Platinum (NiPt), such as Titanium disilicide (TiSi₂), Cobalt disilicide (CoSi₂), and Nickel Platinum Silicide (NiPtSi).

In some embodiments, the conductive thin film may be one or more of following different types of materials: for example, it contains wolfram, aluminum, titanium, copper, nickel, platinum, ruthenium, molybdenum, gold, iridium, rhodium, tantalum, cobalt, and another metal; it may be a metal alloy containing the aforementioned metals; or, it may be a metal oxide, a metal nitride, a metal silicide, a metal carbide, etc., for example, a metal oxide material with relatively high conductivity such as Indium Tin Oxide (ITO), Indium Zinc Oxide (IZO), and Indium Oxide (InO); for example, a metal nitride material such as Titanium Nitride (TiN), Tantalum Nitride (TaN), Wolfram Nitride (WN), and Titanium Aluminum Nitride (TiAlN); or, it may be a polysilicon material, a conductive doped semiconductor material, etc., for example, conductive doped silicon, conductive doped germanium, conductive doped silicon germanium, etc., or another material that embody conductivity, etc.

In some embodiments, the conductive thin film may include an adhesive sublayer and a metal sublayer, the adhesive sublayer may include, but is not limited to, Titanium Nitride (TiN), the metal sublayer may include, but is not limited to, Wolfram (W), i.e., deposition may be performed first to form the adhesive sublayer, and then deposition is performed to form the metal sublayer, such as depositing TiN first and then depositing W, and the TiN may enhance adhesion of W to another film layer.

In some embodiments, the deposition of the connection layer thin film and the deposition of the conductive thin film may be performed using a Chemical Vapor Deposition (CVD) or ALD process.

In some embodiments, the metal sublayer outside a bit line slot T3 may be etched back using a method of dry etching, and then the residual connection layer and adhesive sublayer outside the bit line slot T3 may be washed away through wet etching to ensure that bit lines of two adjacent columns of transistors on two sides of a same trench are separated from each other.

In this embodiment, an impurity concentration of a bottom surface of the semiconductor pillar 10 is doped to be above a concentration required for ohmic contact, contact between the bit line 30 and the bottom of the semiconductor pillar 10 is ohmic contact, and a contact resistance is greatly reduced.

An embodiment of the present disclosure also further an electronic equipment, which includes a semiconductor device described in any one of the foregoing embodiments. In some embodiments, the electronic equipment may include a smart phone, a computer, a tablet computer, an artificial intelligence device, a wearable device, or a smart mobile terminal, a storage apparatus, etc. The storage apparatus may include a memory in a computer, etc., which is not limited here.

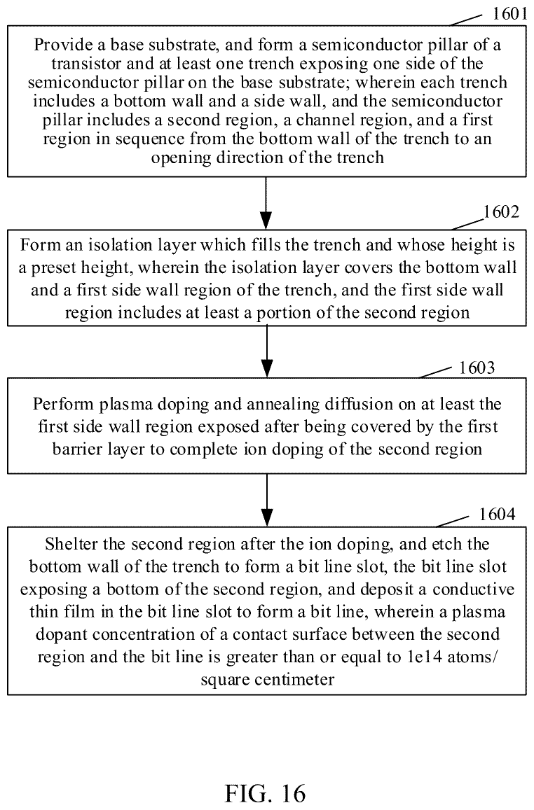

FIG. 16 is a flowchart of a method for manufacturing a semiconductor device according to an embodiment of the present disclosure. As shown in FIG. 16, an embodiment of the present disclosure provides a method for manufacturing a semiconductor device, the semiconductor device includes at least one vertical channel transistor, each transistor includes a semiconductor pillar extending along a direction perpendicular to the base substrate, the method may include following steps.

In step 1601, a base substrate is provided, the semiconductor pillar of each transistor and at least one trench exposing one side of the semiconductor pillar are formed on the base substrate; the trench includes a bottom wall and a side wall, and the semiconductor pillar includes a second region, a channel region, and a first region in sequence from the bottom wall of the trench to an opening direction of the trench; a material of the base substrate satisfies that a band gap of the base substrate is smaller than that of a metal oxide semiconductor.

In step 1602, a first barrier layer covering a second side wall region of the trench and exposing the bottom wall and a first side wall region of the trench is formed, wherein the first side wall region corresponds to the second region of the semiconductor pillar, and the second region is a region to be doped; the second side wall region covers at least the channel region and the first region; the first side wall region is disposed on a side of the second side wall region close to the bottom wall, and the first side wall region includes at least a portion of the second region.

In step 1603, at least the first side wall region exposed after being covered by the first barrier layer is doped and annealed and diffused to complete ion doping of the second region.

In step 1604, the second region after the ion doping is sheltered, and the bottom wall of the trench is etched to form a bit line slot, the bit line slot exposes a bottom of the second region, and a conductive thin film is deposited in the bit line slot to form a bit line, wherein a plasma dopant concentration of a contact surface between the second region and the bit line is greater than or equal to 1e14 atoms/square centimeter.

According to a solution provided in the embodiment, by performing plasma doping and annealing diffusion on the first side wall region (the region includes at least a portion of the second region), compared with a solution of performing plasma doping and annealing diffusion only on the bottom wall, in the solution of the embodiment, the dopant may be quickly diffused to the bottom of the semiconductor pillar, high-concentration doping on a lower surface the a bottom of a semiconductor may be achieved, a contact resistance is reduced, time is short, and an efficiency is high.

In some embodiments, forming the first barrier layer covering the second side wall region of the trench and exposing the bottom wall and the first side wall region of the trench includes: forming an isolation layer which fills the trench and whose height is a preset height, wherein the isolation layer covers the bottom wall and the first side wall region of the trench; forming the first barrier layer covering the second side wall region of the trench; and etching to remove the isolation layer to expose the bottom wall and the first side wall region of the trench.

In some embodiments, when plasma doping and annealing diffusion are performed on the first side wall region, plasma doping and annealing diffusion are also performed on the bottom wall. According to a solution provided in the embodiment of the present disclosure, both the bottom wall and the first side wall region are doped, so that a doping efficiency is higher.

In some embodiments, the formation of at least one semiconductor pillar extending along the direction perpendicular to the base substrate and at least one trench on the base substrate includes: forming a plurality of semiconductor pillars extending along the direction perpendicular to the base substrate and distributed in an array along a first direction and a second direction respectively, and a plurality of trenches extending along the second direction on the base substrate, wherein the trenches expose two opposite sides of two adjacent rows of semiconductor pillars distributed along the second direction, and the first direction and the second direction intersect.

In some embodiments, the bit line slot extends along the first direction, and second regions of semiconductor pillars of a same column distributed along the first direction are connected with a same bit line.

In some embodiments, the isolation layer may be a spin-on hard mask layer including carbon.

In some embodiments, after performing plasma doping and annealing diffusion on the first side wall region, and before etching the bottom wall of the trench to form the bit line slot, the method further includes: removing the first barrier layer to form a second barrier layer covering the first side wall region and the second side wall region of the trench and exposing the bottom wall of the trench; etching the bottom wall of the trench to form the bit line slot includes: etching only on the exposed bottom wall of the trench to form the bit line slot.

In the embodiment, a structure, a material, a related parameter, and a detailed manufacturing process of each film layer have been described in detail in the foregoing embodiments, and will not be repeated here.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure belongs may make any modifications and changes in the form and details of implementation, but the scope of patent protection of the present disclosure shall still be defined by the appended claims.

1. A semiconductor device, comprising: at least one vertical channel transistor disposed on a base substrate, and a bit line; wherein each transistor comprises a semiconductor pillar extending along a direction perpendicular to the base substrate, the semiconductor pillar comprises a channel region, and a first region and a second region respectively disposed on two sides of the channel region, a bit line slot is disposed between a bottom of the second region of the semiconductor pillar and the base substrate, the bit line is filled in the bit line slot, the second region is disposed between the base substrate and the first region, the bit line is in contact with the second region, and a plasma dopant concentration of a contact surface between the second region and the bit line is greater than or equal to 1e14 atoms/square centimeter.

2. The semiconductor device according to claim 1, wherein the plasma dopant concentration of the contact surface between the second region and the bit line is 1e15 to 2e17 atoms/square centimeter.

3. The semiconductor device according to claim 1, comprising a plurality of transistors distributed in an array along a first direction and a second region respectively, and a plurality of bit lines extending along the first direction, wherein second regions of transistors of a same column distributed along the first direction are connected with a same bit line, and the first direction and the second direction intersect.

4. The semiconductor device according to claim 3, wherein each transistor further comprises: a gate electrode surrounding the channel region of the transistor, the semiconductor device further comprises a plurality of word lines extending along the second direction, and gate electrodes of transistors of a same row distributed along the second direction are connected to form one word line.

5. A method for manufacturing a semiconductor device, wherein the semiconductor device comprises at least one vertical channel transistor, the transistor comprises a semiconductor pillar extending along a direction perpendicular to a base substrate, and the method comprises:
providing the base substrate, and forming a semiconductor pillar of each transistor and at least one trench exposing one side of the semiconductor pillar on the base substrate; wherein each trench comprises a bottom wall and a side wall, and the semiconductor pillar comprises a second region, a channel region, and a first region in sequence from the bottom wall of the trench to an opening direction of the trench;
forming a first barrier layer covering a second side wall region of the trench and exposing the bottom wall and a first side wall region of the trench, wherein the first side wall region corresponds to the second region of the semiconductor pillar, and the second region is a region to be doped; and the second side wall region covers at least the channel region and the first region; wherein the first side wall region is disposed on a side of the second side wall region close to the bottom wall, and the first side wall region comprises at least a portion of the second region;
performing plasma doping and annealing diffusion on at least the first side wall region exposed after being covered by the first barrier layer to complete ion doping of the second region;
sheltering the second region after the ion doping, and etching the bottom wall of the trench to form a bit line slot, wherein the bit line slot exposes a bottom of the second region, and depositing a conductive thin film in the bit line slot to form a bit line, wherein a plasma dopant concentration of a contact surface between the second region and the bit line is greater than or equal to 1e14 atoms/square centimeter.

6. The method for manufacturing the semiconductor device according to claim 5, wherein forming the first barrier layer covering the second side wall region of the trench and exposing the bottom wall and the first side wall region of the trench comprises:
forming an isolation layer which fills the trench and whose height is a preset height, wherein the isolation layer covers the bottom wall and the first side wall region of the trench;
forming the first barrier layer covering the second side wall region of the trench; and
etching to remove the isolation layer to expose the bottom wall and the first side wall region of the trench.

7. The method for manufacturing the semiconductor device according to claim 6, wherein the isolation layer is a spin-on hard mask layer comprising carbon.

8. The method for manufacturing the semiconductor device according to claim 5, wherein after performing the plasma doping and the annealing diffusion on the first side wall region and before etching the bottom wall of the trench to form the bit line slot, the method further comprises:
removing the first barrier layer to form a second barrier layer covering the first side wall region and the second side wall region of the trench and exposing the bottom wall of the trench.

9. The method for manufacturing the semiconductor device according to claim 5, wherein when performing the plasma doping and the annealing diffusion on the first side wall region, the plasma doping and the annealing diffusion is also performed on the bottom wall.

10. The method for manufacturing the semiconductor device according to claim 5, wherein forming the at least one semiconductor pillar extending along the direction perpendicular to the base substrate and the at least one trench on the base substrate comprises:
forming a plurality of semiconductor pillars extending along the direction perpendicular to the base substrate and distributed in an array along a first direction and a second direction respectively, and a plurality of trenches extending along the second direction on the base substrate, wherein each trench expose two opposite sides of two adjacent rows of semiconductor pillars distributed along the second direction, and the first direction and the second direction intersect.

11. The method for manufacturing the semiconductor device according to claim 10, wherein the bit line slot extends along the first direction, and second regions of semiconductor pillars of a same column distributed along the first direction are connected with a same bit line.

12. An electronic equipment, comprising the semiconductor device according to claim 1.

13. The electronic equipment according to claim 12, wherein the electronic equipment is a smart phone, a computer, a tablet computer, an artificial intelligence device, a wearable device, or a smart mobile terminal.
